(19) United States
(12) Patent Application Publication
(10) Pub. No.: US 2024/0379574 A1
(43) Pub. Date: Nov. 14, 2024

(54) SEMICONDUCTOR DEVICE

(71) Applicant: ROHM CO., LTD., Kyoto-shi, Kyoto (JP)

(72) Inventors: Yoshizo OSUMI, Kyoto-shi (JP); Taro NISHIOKA, Kyoto-shi (JP)

(21) Appl. No.: 18/777,194

(22) Filed: Jul. 18, 2024

Related U.S. Application Data
(63) Continuation of application No. PCT/JP2022/047430, filed on Dec. 22, 2022.

(30) Foreign Application Priority Data
Jan. 20, 2022 (JP) 2022-007105

(51) Int. Cl. H01L 23/538; H01L 23/00; H01L 23/495; H01L 23/64; H01L 25/065

(52) U.S. Cl. CPC H01L 23/5386; H01L 23/49503; H01L 23/645; H01L 25/0655; H01L 24/48; H01L 2224/48159; H01L 2224/48245; H01L 2924/182

(57) ABSTRACT

A semiconductor device is configured to suppress an occurrence of dielectric breakdown in the semiconductor device. The semiconductor device includes an insulating element, a conductive member on which the insulating element is mounted, and a sealing resin covering the insulating element. The conductive member includes an uneven part covered by the sealing resin. As an example, in the semiconductor device, the conductive member includes a first die pad on which the insulating element is mounted, and the uneven part includes a first region that is provided on the first die pad.

### TECHNICAL FIELD

The present disclosure relates to a semiconductor device.

### BACKGROUND ART

Conventionally, inverter devices are used for electric vehicles (including hybrid vehicles) or household electrical appliances. For such an inventor device, a semiconductor device with an insulating element is used. Such an inverter device includes a number of (e.g. six) power semiconductors such as (Insulated Gate Bipolar Transistor) or MOSFETs (Metal Oxide Semiconductor Field Effect Transistor) in addition to a semiconductor device. The semiconductor device includes a controlling element, an insulating element, and a driving element. In the inverter device, a control signal output from an ECU (Engine Control Unit) is input to the controlling element of the semiconductor device. The controlling element converts the control signal into a PWM (Pulse Width Modulation) control signal and transmits it to the driving element through the insulating element. Based on the PWM control signal, the driving element drives the power semiconductors to perform a switching operation at appropriate timings. Each of the six switching elements perform switching operation at appropriate timings to generate three-phase AC power for motor driving from DC power of an in-vehicle battery. An example of a semiconductor device with an insulating element is disclosed in JP-A-2016-207714.

### BRIEF DESCRIPTION OF THE DRAWINGS

FIG. 1 is a plan view illustrating a semiconductor device according to a first embodiment of the present disclosure.

FIG. 2 is a plan view illustrating the semiconductor device of FIG. 1, in which a sealing resin is transparent.

FIG. 3 is a front view illustrating the semiconductor device of FIG. 1.

FIG. 4 is a left side view illustrating the semiconductor device of FIG. 1.

FIG. 5 is a sectional view taken along a line V-V of FIG. 2.

FIG. 6 is a partially enlarged view of FIG. 5.

FIG. 7 is a sectional view taken along a line VII-VII of FIG. 2.

FIG. 8 is a partially enlarged view of FIG. 7.

FIG. 9 is a perspective view of a first die pad.

FIG. 10 is a plan view of f a step related to a manufacturing method of the semiconductor device in FIG. 1.

FIG. 11 is a plan view of a step related to a manufacturing method of the semiconductor device in FIG. 1.

FIG. 12 is a perspective view illustrating a first die pad 3 according to a first variation of the first embodiment.

FIG. 13 is a perspective view illustrating a first die pad 3 according to a second variation of the first embodiment.

FIG. 14 is a perspective view illustrating a first die pad 3 according to a third variation of the first embodiment.

FIG. 15 is a perspective view illustrating a first die pad 3 according to a fourth variation of the first embodiment.

FIG. 16 is a plan view illustrating a semiconductor device according to a second embodiment of the present disclosure, in which a sealing resin is transparent

FIG. 17 is a plan view illustrating a semiconductor device according to a third embodiment of the present disclosure, in which a sealing resin is transparent

FIG. 18 is a perspective view illustrating a first die pad 3 in the semiconductor device of FIG. 17.

FIG. 19 is a perspective view illustrating a first die pad 3 according to a first variation of the third embodiment.

FIG. 20 is a plan view illustrating a semiconductor device according to a fourth embodiment of the present disclosure, in which a sealing resin is transparent

FIG. 21 is a plan view illustrating a semiconductor device according to a fifth embodiment of the present disclosure, in which a sealing resin is transparent

FIG. 22 is a plan view illustrating a semiconductor device according to a sixth embodiment of the present disclosure, in which a sealing resin is transparent

### DETAILED DESCRIPTION OF EMBODIMENTS

The following describes mode for carrying out the present disclosure with reference to the accompanying drawings.

### First Embodiment

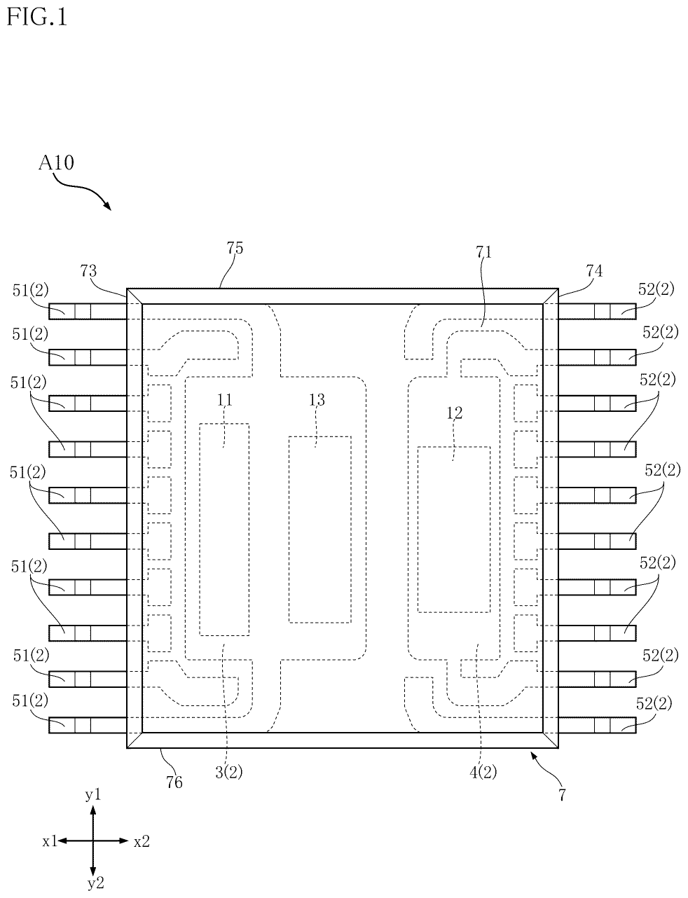

FIGS. 1 to 9 show an example of a semiconductor device according to the present disclosure. A semiconductor device A10 of the present embodiment includes a first semiconductor element 11, a second semiconductor element 12, an insulating element 13, a conductive member 2, pluralities of wires 61 to 64, and a sealing resin 7. The conductive member 2 includes a first die pad 3, a second die pad 4, a plurality of first terminals 51, a plurality of second terminals 52, pluralities of pad parts 53, 55, a pair of connection parts 54, and a pair of connection parts 56. The semiconductor device A10 is configured to be surface-mounted on a wiring board of an inverter device in an electric vehicle (or a hybrid vehicle), for example. The application and function of the semiconductor device A10 are not limited. The package type of the semiconductor device A10 is SOP (Small Outline Package). The package type of the semiconductor device A10 is not limited to the SOP.

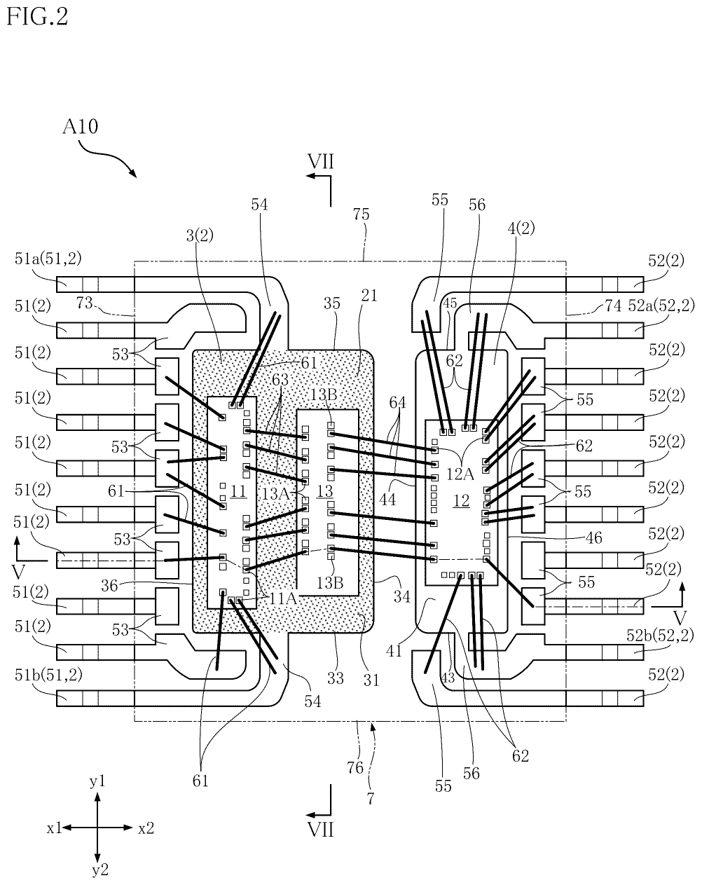

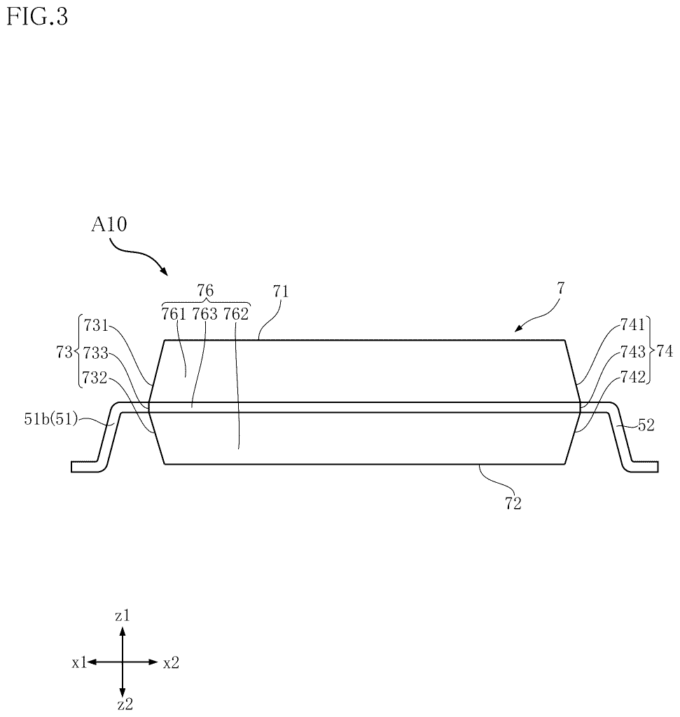

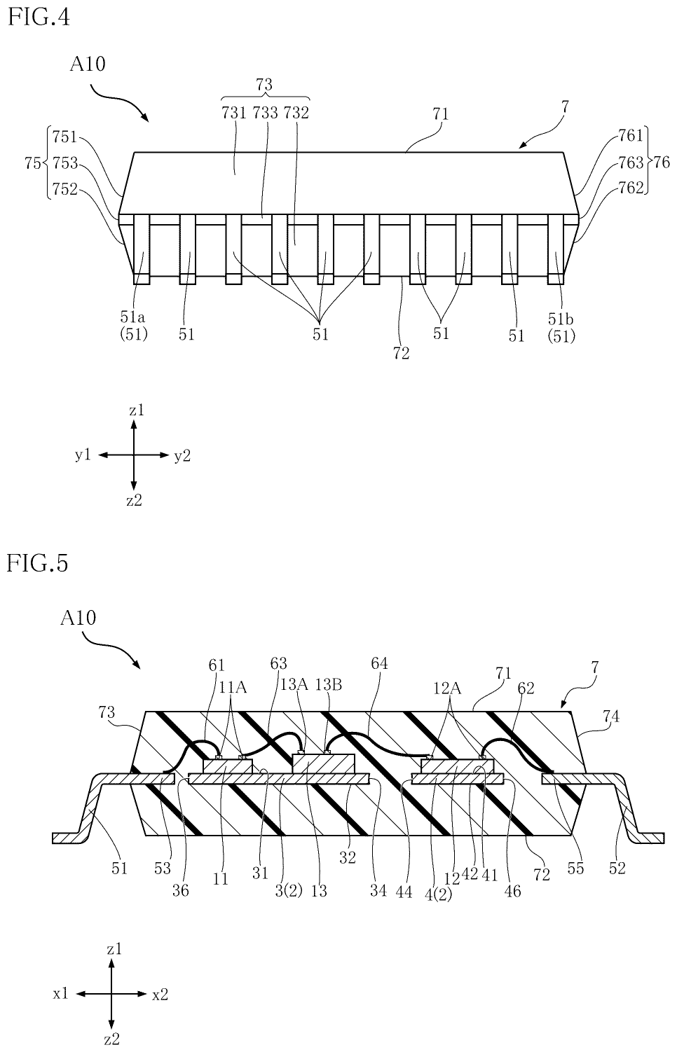

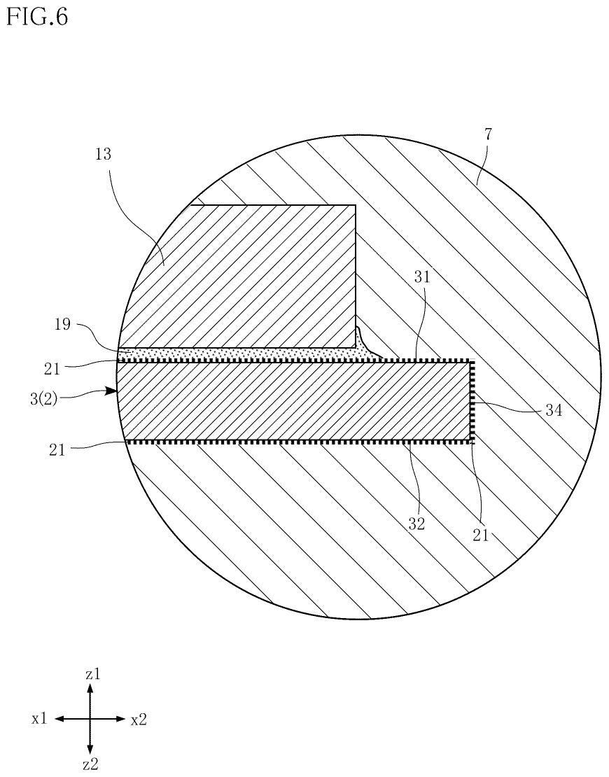

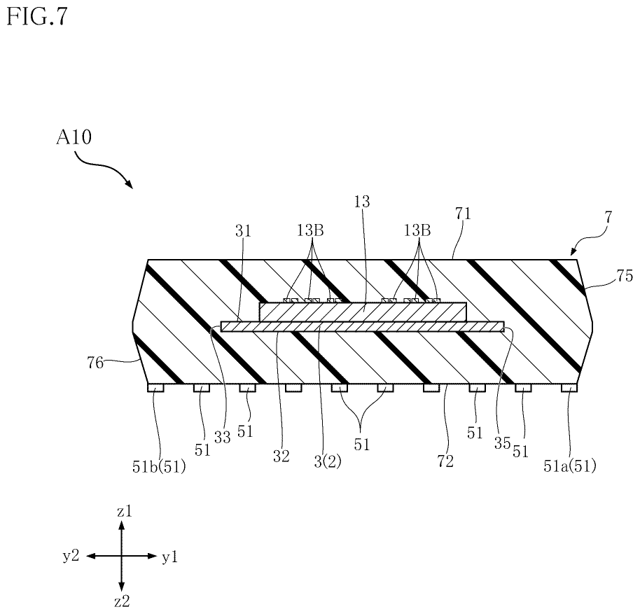

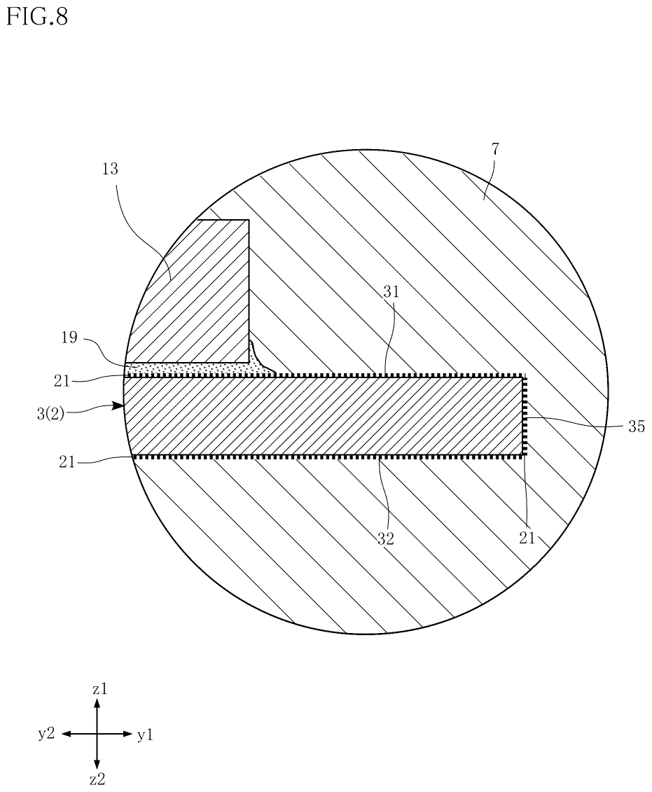

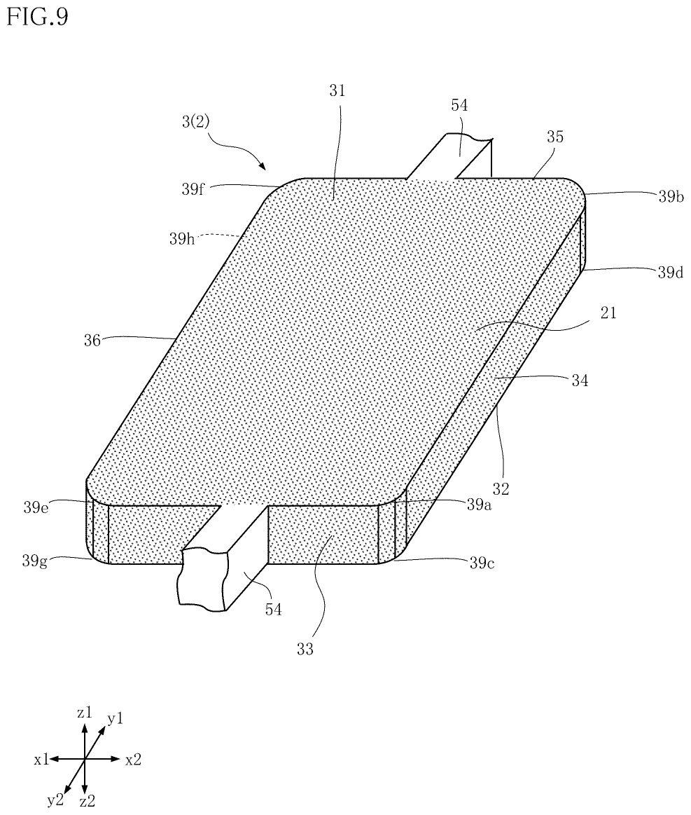

FIG. 1 is a plan view illustrating the semiconductor device A10. FIG. 2 is a plan view illustrating the semiconductor device A10. In FIG. 2, for the sake of convenience of understanding, the sealing resin 7 is transparent and an outer shape of the sealing resin 7 is indicated by an imaginary line (a two-dot chain line). FIG. 3 is a front view illustrating the semiconductor device A10. FIG. 4 is a left side view illustrating the semiconductor device A10. FIG. 5 is a sectional view taken along a line V-V of FIG. 2. FIG. 6 is a partially enlarged view of FIG. 5. FIG. 7 is a sectional view taken along a line VII-VII of FIG. 2. FIG. 8 is a partially enlarged view of FIG. 7. FIG. 9 is a perspective view illustrating the first die pad 3.

The semiconductor device A10 has a rectangular shape as viewed in a thickness direction (plan view). For the sake of convenience of explanation, the thickness direction of the semiconductor device A10 is referred to as a z direction, a direction (horizontal direction in FIGS. 1 and 2) along one side of the semiconductor device A10 perpendicular to the z direction is referred to as a x direction, and a direction (vertical direction in FIGS. 1 and 2) perpendicular to the z direction and the x direction is referred to as a y direction. The shape and each dimension of the semiconductor device A10 are not limited.

The first semiconductor element the 11, second semiconductor element 12 and the insulating element 13 are the core components for the functions of the semiconductor device A10.

As shown in FIG. 2, the first semiconductor element 11 is mounted on a portion of the conductive member 2 (a first die pad 3 to be described later) and is disposed at the center of the semiconductor device A10 in the y direction and closer to the x1 side in the x direction. As viewed in the z direction, the first semiconductor element 11 has a rectangular shape with the long side in the y direction. The first semiconductor element 11 is a controlling element. The first semiconductor element 11 includes a circuit for converting a control signal input from an ECU or the like into a PWM control signal, a transmitting circuit for transmitting the PWM control signal to the second semiconductor element 12, and a receiving circuit for receiving an electric signal from the second semiconductor element 12.

As shown in FIG. 2, the second semiconductor element 12 is mounted on a portion of the conductive member 2 (a second die pad 4 to be described later) and is disposed at the center of the semiconductor device A10 in the y direction and closer to the x2 side in the x direction. As viewed in the z direction, the second semiconductor element 12 has a rectangular shape with the long side in the y direction. The second semiconductor element 12 is a driving element. The second semiconductor element 12 includes a receiving circuit for receiving a PWM control signal transmitted from the first semiconductor element 11, a circuit (a gate driver) for outputting after generating a driving signal for the switching element (e.g. IGBT or MOSFET) based on the received PWM control signal, and a transmitting circuit for transmitting an electric signal to the first semiconductor element 11.

As shown in FIG. 2, the insulating element 13 is mounted on a portion of the conductive member 2 (a first die pad 3) and is disposed at the center of the semiconductor device A10 in the y direction. The insulating element 13 is located at the x2 side in the x direction with respect to the first semiconductor element 11 and at the x1 side in the x direction with respect to the second semiconductor element 12. In other words, the insulating element 13 is located between the first semiconductor element 11 and the second semiconductor element 12 in the x direction. As viewed in the z direction, the insulating element 13 has a rectangular shape with the long side in the y direction. The insulating element 13 is an element that transmits a PWM control signal and other electric signals in an insulated condition. The insulating element 13 receives the PWM control signal from the first semiconductor element 11 via the wires 63, and transmits the received PWM signal to the second semiconductor element 12 via the wires 64 in an insulated condition. Further, the insulating element 13 receives the electric signal from the second semiconductor element 12 via the wires 64, and transmits the received electric signal to the first semiconductor element 11 via the wires 63 in an insulated condition. In other words, the insulating element 13 insulates the first semiconductor element 11 and the second semiconductor element 12 from each other while relaying signals between the first semiconductor element 11 and the second semiconductor element 12.

In the present embodiment, the insulating element 13 is an inductive type insulating element. The inductive type insulating element includes two inductively coupled inductors (coils) to transmit electric signals in an insulated state. The insulating element 13 has a substrate made of Si, on which inductors made of Cu are formed. The inductors include a transmitting-side inductor and a receiving-side inductor, which are stacked in the thickness direction of the insulating element 13 (the z direction). A dielectric layer made of SiO₂ or the like is interposed between the transmitting-side inductor and the receiving-side inductor. The dielectric layer provides electrical insulation between the transmitting-side inductor and the receiving-side inductor. Although the present embodiment shows the case where the insulating element 13 is an inductive type insulating element, the insulating element 13 may be a capacitive type. An example of a capacitive type insulating element is a capacitor.

The first semiconductor element 11 transmits the PWM control signal to the second semiconductor element 12 via the insulating element 13. The first semiconductor element 11 may also transmit signals other than the PWM control signal to the second semiconductor element 12. The second semiconductor element 12 transmits the electric signals to the first semiconductor element 11 via the insulating element 13. Information indicated by the electric signals that the second semiconductor element 12 transmits to the first semiconductor element 11 is not limited.

Generally, a half-bridge circuit in which a low-side switching element and a high-side switching element are connected in a totem pole shape is used for a motor driver circuit in an inverter device of a hybrid vehicle or the like. In an insulated gate driver, a switch that turns on at a given time point is only one of either the low-side switching element or the high-side switching element. In a high-voltage region, since a source of the low-side switching element and a reference potential of the insulated gate driver that drives the switching element are connected to the ground, a gate-source voltage operates with reference to the ground. On the other hand, a source of the high-side switching element and a reference potential of the insulated gate driver that drives the switching element are connected to an output node of the half-bridge circuit. Since a potential of the output node of the half-bridge circuit changes depending on whether the low-side switching element or the high-side switching element is turned on, the reference potential of the insulated gate driver that drives the high-side switching element changes. When the high-side switching element is turned on, the reference potential becomes a voltage (for example, 600V or higher) equivalent to a voltage applied to a drain of the high-side switching element. The respective grounds of the first semiconductor element 11 and the second semiconductor element 12 are separated from each other in order to ensure insulation. When the semiconductor device A10 is used as an insulated gate driver that drives the high-side switching element, a voltage equal to or higher than 600V is transiently applied to the second semiconductor element 12 as compared with a ground of the first semiconductor element 11. Because of a significant potential difference between the first semiconductor element 11 and the second semiconductor element 12, in the semiconductor device A10, an input-side circuit including the second semiconductor element 12 and an output-side circuit including the first semiconductor element 11 are insulated by the insulating element 13. That is, the insulating element 13 insulates the input-side circuit with a relatively low potential and the output-side circuit with a relatively high potential.

As shown in FIG. 2, a plurality of electrodes 11A is provided on the upper surface (the surface facing the z1 side) of the first semiconductor element 11. The electrodes 11A electrically conduct to the circuit composed in the first semiconductor element 11. Similarly, a plurality of electrodes 12A is provided on the upper surface (the surface facing the z1 side) of the second semiconductor element 12. The electrodes 12A electrically conduct to the circuit composed in the second semiconductor element 12. Further, a plurality of first electrodes 13A and a plurality of second electrodes 13B are provided on the upper surface (the surface facing the z1 side) of the insulating element 13. Each of the first electrodes 13A and the second electrodes 13B is electrically connected to either the transmitting-side inductor or the receiving-side inductor. In the insulating element 13, the first electrodes 13A are arranged closer to the x1 side in the x direction and along the y direction. The second electrodes 13B are arranged closer to the center in the x direction and along the y direction.

In the semiconductor device A10, the conductive member 2 is a component that constitutes a conduction path through a wiring board of an inverter device, the first semiconductor element 11 and the second semiconductor element 12. The conductive member 2 is made of an alloy containing Cu, for example. The conductive member 2 is formed from a lead frame 81 to be described later. The conductive member 2 supports the first semiconductor element 11, the second semiconductor element 12 and the insulating element 13. As shown in FIG. 2, the conductive member 2 includes a first die pad 3, a second die pad 4, a plurality of first terminals 51, a plurality of second terminals 52, pluralities of pad parts 53, 55, a pair of connection parts 54, and a pair of connection parts 56.

The first die pad 3 is disposed at the center of the semiconductor device A10 in the y direction and closer to the x1 side in the x direction. The second die pad 4 is disposed at the x2 side in the x direction with respect to the first die pad 3 and is spaced apart from the first die pad 3.

As shown in FIGS. 2 and 5, the first die pad 3 supports the first semiconductor element 11 and the insulating element 13. The first die pad 3 is electrically connected to the first semiconductor element 11 and is an element of the above-mentioned input-side circuit. As viewed in the z direction, the first die pad 3 has a rectangular shape (or substantially a rectangular shape), for example. The first die pad 3 has an obverse surface 31 and a reverse surface 32. As shown in FIGS. 5 and 7, the obverse surface 31 and the reverse surface 32 are spaced apart from each other in the z direction. The obverse surface 31 faces the z1 side, and the reverse surface 32 faces the z2 side. The obverse surface 31 supports the first semiconductor element 11 and the insulating element 13. Further, the first die pad 3 has side surfaces 33 to 36. Each of the side surfaces 33 to 36 is connected to the obverse surface 31 and the reverse surface 32 and is sandwiched between the obverse surface 31 and the reverse surface 32 in the z direction. As shown in FIGS. 2 and 7, the side surface 33 and the side surface 35 are spaced apart from each other in the y direction. The side surface 33 faces the y2 side, and the side surface 35 faces the y1 side. As shown in FIGS. 2 and 5, the side surface 34 and the side surface 36 are spaced apart from each other in the x direction and connected to the side surface 33 and the side surface 35. The side surface 34 faces the x2 side, and the side surface 36 faces the x1 side.

Each of the obverse surface 31, the reverse surface 32, and the side surfaces 33 to 36 is not limited to a flat surface and may include a curved surface. In the present embodiment, since each of the obverse surface 31 and the reverse surface 32 has four corners which are not square but curved, both edges of the side surfaces 33 to 36 in the x direction or the y direction are curved.

As shown in FIG. 9, the first die pad 3 has corner parts 39a to 39h. The corner part 39a is a portion where the obverse surface 31, the side surface 33 and the side surface 34 are connected to each other. The corner part 39b is a portion where the obverse surface 31, the side surface 34 and the side surface 35 are connected to each other. The corner part 39c is a portion where the reverse surface 32, the side surface 33 and the side surface 34 are connected to each other. The corner part 39d is a portion where the reverse surface 32, the side surface 34 and the side surface 35 are connected to each other. The corner part 39e is a portion where the obverse surface 31, the side surface 33 and the side surface 36 are connected to each other. The corner part 39f is a portion where the obverse surface 31, the side surface 35 and the side surface 36 are connected to each other. The corner part 39g is a portion where the reverse surface 32, the side surface 33 and the side surface 36 are connected to each other. The corner part 39h is a portion where the reverse surface 32, the side surface 35 and the side surface 36 are connected to each other.

An uneven part 21 is provided on the first die pad 3. The uneven part 21 is a portion where a fine irregularity is formed, with the surface roughness greater than the portion of the conductive member 2 without the uneven part 21. The uneven part 21 is covered by the sealing resin 7. In the present embodiment, fine recesses are irregularly formed in the uneven part 21. In FIGS. 2 and 9, the region where the uneven part 21 is provided is stippled. In the present embodiment, as shown in FIGS. 2, 6, 8, and 9, the uneven part 21 is provided on the entire surface of each of the obverse surface 31, the reverse surface 32, and the side surfaces 33 to 36 of the first die pad 3. In the present embodiment, the uneven part 21 is formed by an etching process as described in the manufacturing method below. The method of forming the uneven part 21 is not limited. For example, the uneven part 21 may be formed by a shot blast process or the like. The uneven part 21 does not need to be provided on the entire surface (may be provided only on a part) of each surface, and does not need to be provided on all (may be provided only on one) of the obverse surface 31, the reverse surface 32, and the side surfaces 33 to 36.

As shown in FIGS. 6 and 8, the first semiconductor element 11 and the insulating element 13 are bonded to the obverse surface 31 of the first die pad 3 by a conductive bonding material 19. In the present embodiment, the conductive bonding material 19 includes a solder. The conductive bonding material 19 is not limited and may be a metal paste, a sintered metal or the like.

As shown in FIGS. 2 and 5, the second die pad 4 supports the second semiconductor element 12. The second die pad 4 is electrically connected to the second semiconductor element 12 and is an element of the above-mentioned output-side circuit. As viewed in the z direction, the second die pad 4 has a rectangular shape (or substantially a rectangular shape), for example. The second die pad 4 has an obverse surface 41 and a reverse surface 42. As shown in FIG. 5, the obverse surface 41 and the reverse surface 42 are spaced apart from each other in the z direction. The obverse surface 41 faces the z1 side, and the reverse surface 42 faces the z2 side. The obverse surface 41 supports the second semiconductor element 12. Further, the second die pad 4 has side surfaces 43 to 46. Each of the side surfaces 43 to 46 is connected to the obverse surface 41 and the reverse surface 42 and is sandwiched between the obverse surface 41 and the reverse surface 42 in the z direction. As shown in FIG. 2, the side surface 43 and the side surface 45 are spaced apart from each other in the y direction. The side surface 43 faces the y2 side, and the side surface 45 faces the y1 side. As shown in FIGS. 2 and 5, the side surface 44 and the side surface 46 are spaced apart from each other in the x direction and connected to the side surface 43 and the side surface 45. The side surface 44 faces the x1 side, and the side surface 46 faces the x2 side.

Each of the obverse surface 41, the reverse surface 42, and the side surfaces 43 to 46 is not limited to a flat surface and may include a curved surface. In the present embodiment, since each of the obverse surface 41 and the reverse surface 42 has four corners which are not square but curved, both edges of the side surfaces 43 to 46 in the x direction or the y direction are curved. The second semiconductor element 12 is bonded to the obverse surface 41 of the second die pad 4 by the conductive bonding material 19.

The first terminals 51 are components that is bonded to a wiring board of an inverter device to constitute a conduction path through the semiconductor device A10 and the wiring board. Each of the first terminals 51 is electrically connected to the first semiconductor element 11 appropriately and is an element of the above-mentioned input-side circuit. As shown in FIGS. 1, 2, and 4, the first terminals 51 are spaced apart from each other to be arranged at regular intervals along the y direction. The first terminals 51 are located at the x1 side in the x direction with respect to the first die pad 3 and protrude from the sealing resin 7 (a resin side surface 73 to be described later) to the x1 side in the x direction. The first terminals 51 include a power supply terminal to which a voltage is supplied, a ground terminal, an input terminal into which a control signal is input, an input terminal into which other electric signals are input, and an output terminal to output other electric signals. In the present embodiment, the semiconductor device A10 includes 10 first terminals 51. The number of first terminals 51 is not limited. The signal input/output by each first terminal 51 is not limited.

Each first terminal 51 has an elongated rectangular shape extending along the x direction, and includes a portion exposed from the sealing resin 7 and a portion covered with the sealing resin 7. As shown in FIGS. 3 and 5, the portion of the first terminal 51 exposed from the sealing resin 7 is bent in a gull wing shape. The portion of the first terminal 51 exposed from the sealing resin 7 may be subjected to a plating treatment. A plating layer formed by the plating treatment is made of, for example, an alloy containing Sn, such as solder, and covers the portion exposed from the sealing resin 7. When the semiconductor device A10 is surface-mounted on a wiring board of the inverter device by solder bonding, the plating layer prevents erosion of the exposed portion due to the solder bonding while improving the adhesion of solder to the exposed portion. The first terminals 51 include a first terminal 51a and a first terminal 51b. The first terminal 51a is disposed at the uppermost y1 side in the y direction among the first terminals 51. The first terminal 51b is disposed at the lowermost y2 side in the y direction among the first terminals 51.

The pad parts 53 are connected to the first terminals 51 except for the first terminals 51a, 51b at the x2 side in the x direction, respectively. The shape of each pad part 53 as viewed in the z direction is not limited. An upper surface (a surface facing the z1 side) of each pad part 53 is flat (or substantially flat), to which a wire 61 to be described later is bonded. The upper surface of each pad part 53 may be subjected to a plating treatment. A plating layer formed by the plating treatment is made of, for example, a metal containing Ag, and covers the upper surface of the pad part 53. The plating layer protects the lead frame 81 (to be described later) from an impact during a wire bonding of the wire 61 (to be described later) while increasing bonding strength of the plurality of wires 61. The pad part 53 is covered with the sealing resin 7 over the entire surface.

The pair of connection parts 54 are connected to the first die pad 3, and the first terminal 51a or the first terminal 51b. The connection part 54 connected to the first terminal 51a extends in the y direction, whose end at the y2 side in the y direction is connected to an end of the first die pad 3 at the y1 side in the y direction near the center in the x direction. The connection part 54 connected to the first terminal 51b extends in the y direction, whose end at the y1 side in the y direction is connected to an end of the first die pad 3 at the y2 side in the y direction near the center in the x direction. In this way, the first terminal 51a and the first terminal 51b are connected to the first die pad 3 via the pair of connection parts 54 and hold the first die pad 3. An upper surface (a surface facing the z1 side) of each connection part 54 is flat (or substantially flat), to which the wire 61 is bonded. The upper surface of each connection part 54 may be covered by a plating layer (e.g. a metal containing Ag), as with the upper surface of the pad part 53. The connection parts 54 are covered by the sealing resin 7 over the entire surface.

As with the first terminals 51, the second terminals 52 are components that are bonded to a wiring board of an inverter device to constitute a conduction path through the semiconductor device A10 and the wiring board. Each of the second terminals 52 is electrically connected to the second semiconductor element 12 appropriately and is an element of the above-mentioned output-side circuit. As shown in FIGS. 1 and 2, the second terminals 52 are spaced apart from each other to be arranged at regular intervals along the y direction. The second terminals 52 are located at the x2 side in the x direction with respect to the second die pad 4 and protrude from the sealing resin 7 (a resin side surface 74 to be described later) to the x2 side in the x direction. The second terminals 52 include a power supply terminal to which a voltage is supplied, a ground terminal, an output terminal to output a driving signal, an input terminal into which other electric signals are input, and an output terminal to output other electric signals. In the present embodiment, the semiconductor device A10 includes 10 second terminals 52. The number of second terminals 52 is not limited. The signal input/output by each second terminal 52 is not limited.

Each second terminal 52 has an elongated rectangular shape extending along the x direction, and includes a portion exposed from the sealing resin 7 and a portion covered with the sealing resin 7. As shown in FIGS. 3 and 5, the portion of the second terminal 52 exposed from the sealing resin 7 is bent in a gull wing shape. The portion of the second terminal 52 exposed from the sealing resin 7 may be formed with a plating layer (e.g. an alloy containing Sn, such as solder), as with the first terminal 51. The second terminals 52 include a second terminal 52a and a second terminal 52b. The second terminal 52a is the second one from the y1 side in the y direction among the second terminals 52. The second terminal 52b is the second one from the y2 side in the y direction among the second terminals 52.

The pad parts 55 are connected to the second terminals 52 except for the second terminals 52a, 52b at the x1 side in the x direction. The shape of each pad part 55 as viewed in the z direction is not limited. An upper surface (a surface facing the z1 side) of each pad part 55 is flat (or substantially flat), to which the wire 62 to be described later is bonded. The upper surface of the pad part 55 may be covered by a plating layer (e.g. a metal containing Ag), as with the upper surface of the pad part 53. The pad part 55 is covered by the sealing resin 7 over the entire surface.

The pair of connection parts 56 are connected to the second die pad 4, and the second terminal 52a or the second terminal 52b. The connection part 56 connected to the second terminal 52a has an end at the y2 side in the y direction that is connected to an end of the second die pad 4 at the y1 side in the y direction near the center in the x direction. The connection part 56 connected to the second terminal 52b has an end at the y1 side in the y direction that is connected to an end of the second die pad 4 at the y2 side in the y direction near the center in the x direction. In this way, the second terminal 52a and the second terminal 52b are connected to the second die pad 4 via the pair of connection parts 56 and hold the second die pad 4. An upper surface (a surface facing the z1 side) of each connection part 56 is flat (or substantially flat), to which the wire 62 is bonded. The upper surface of each connection part 56 may be covered by a plating layer (e.g. a metal containing Ag), as with the upper surface of the pad part 53. The connection parts 56 are covered by the sealing resin 7 over the entire surface.

The shape of the conductive member 2 is not limited to the above. For example, the first die pad 3 may be held by any one of the first terminals 51. In other words, the pair of connection parts 54 are connected to the first die pad 3 and any one of the first terminals 51. Also, the second die pad 4 may be held by any one of the second terminals 52. In other words, the pair of connection parts 56 are connected to the second die pad 4 and any one of the second terminals 52.

As shown in FIG. 2, the pluralities of wires 61 to 64 together with the conductive member 2 constitute conduction paths so that the first semiconductor element 11, the second semiconductor element 12, and the insulating element 13 perform predetermined functions. The material of each of the pluralities of wires 61 to 64 is metal including, for example, Au, Cu, or Al.

As shown in FIGS. 2 and 5, the plurality of wires 61 constitutes conduction paths through the first semiconductor element 11 and the first terminals 51. The first semiconductor element 11 is electrically connected to at least one of the first terminals 51 by the plurality of wires 61. The plurality of wires 61 is one element of the above-mentioned input-side circuit. As shown in FIG. 2, each wire 61 has one end electrically bonded to any electrode 11A of the first semiconductor element 11 and another end electrically bonded to any one of the pad parts 53 and the pair of connection parts 54. The number of wires 61 bonded to each pad part 53 and each connection part 54 is not limited.

As shown in FIGS. 2 and 5, the plurality of wires 62 constitutes conduction paths through the second semiconductor element 12 and the second terminals 52. The second semiconductor element 12 is electrically connected to at least one of the second terminals 52 by the plurality of wires 62. The plurality of wires 62 is one element of the above-mentioned output-side circuit. As shown in FIG. 2, each wire 62 has one end electrically bonded to any electrode 12A of the second semiconductor element 12 and another end electrically bonded to any one of the pad parts 55 and the pair of connection parts 56. The number of wires 62 bonded to each pad part 55 and each connection part 54 is not limited.

As shown in FIGS. 2 and 5, the plurality of wires 63 constitutes conduction paths through the first semiconductor element 11 and the insulating element 13. The first semiconductor element 11 and the insulating element 13 are electrically connected to each other by the plurality of wires 63. The plurality of wires 63 is one element of the above-mentioned input-side circuit. As shown in FIG. 2, each wire 63 is electrically bonded to any electrode 11A of the first semiconductor element 11 and any first electrode 13A of the insulating element 13.

As shown in FIGS. 2 and 5, the plurality of wires 64 constitutes conduction paths through the second semiconductor element 12 and the insulating element 13. The second semiconductor element 12 and the insulating element 13 are electrically connected to each other by the plurality of wires 64. The plurality of wires 64 is one element of the above-mentioned output-side circuit. As shown in FIG. 2, each wire 64 is electrically bonded to any electrode 12A of the second semiconductor element 12 and any second electrode 13B of the insulating element 13.

As shown in FIG. 1, the sealing resin 7 covers the first semiconductor element 11, the second semiconductor element 12, the insulating element 13, the first die pad 3, the second die pad 4, the pair of connection parts 54, the pair of connection parts 56, the pluralities of pad parts 53, 55, the pluralities of wires 61 to 64, and a portion of each of the first terminals 51 and the second terminals 52. The sealing resin 7 has electrical insulation. The sealing resin 7 is made of a material containing, for example, a black epoxy resin. As viewed in the z direction, the sealing resin 7 has a rectangular shape.

As shown in FIGS. 3 and 4, the sealing resin 7 has a resin top surface 71, a resin bottom surface 72, resin side surfaces 73 to 76.

The resin top surface 71 and the resin bottom surface 72 are spaced apart from each other in the z direction. The resin top surface 71 and the resin bottom surface 72 face opposite side in the z direction. The resin top surface 71 is located at the z1 side in the z direction and faces the z1 side like the obverse surface 31 of the first die pad 3. The resin bottom surface 72 is located at the z2 side in the z direction and faces the z2 side like the reverse surface 32 of the first die pad 3. Each of the resin top surface 71 and the resin bottom surface 72 is flat (or substantially flat).

Each of the resin side surfaces 73 to 76 is connected to the resin top surface 71 and the resin bottom surface 72 and is sandwiched between the resin top surface 71 and the resin bottom surface 72 in the z direction. The resin side surface 73 and the resin side surface 74 are spaced apart from each other in the x direction. The resin side surface 73 and the resin side surface 74 face opposite side in the x direction. The resin side surface 73 is located at the x1 side in the x direction, and the resin side surface 74 is located at the x2 side in the x direction. The resin side surface 75 and the resin side surface 76 are spaced apart from each other in the y direction and are connected to the resin side surface 73 and the resin side surface 74. The resin side surface 75 and the resin side surface 76 face opposite side in the y direction. The resin side surface 75 is located at the y1 side in the y direction, and the resin side surface 76 is located at the y2 side in the y direction. As shown in FIG. 1, a portion of each of the first terminals 51 protrudes from the resin side surface 73. Further, a portion of each of the second terminals 52 protrudes from the resin side surface 74.

As shown in FIGS. 3 and 4, the resin side surface 73 includes a resin first region 731, a resin second region 732, and a resin third region 733. The resin first region 731 has one end in the z direction that is connected to the resin top surface 71, and has another end in the z direction that is connected to the resin third region 733. The resin first region 731 is inclined with respect to the resin top surface 71 and the y-z plane. The resin second region 732 has one end in the z direction that is connected to the resin bottom surface 72, and has another end in the z direction that is connected to the resin third region 733. The resin second region 732 is inclined with respect to the resin bottom surface 72 and the y-z plane. The resin third region 733 has one end in the z direction that is connected to the resin first region 731, and has another end in the z direction that is connected to the resin second region 732. The resin third region 733 is along the y-z plane. As viewed in the z direction, the resin third region 733 is located outside the resin top surface 71 and the resin bottom surface 72. A portion of each of the first terminals 51 is exposed from the resin third region 733.

As shown in FIG. 3, the resin side surface 74 includes a resin fourth region 741, a resin fifth region 742, and a resin sixth region 743. The resin fourth region 741 has one end in the z direction that is connected to the resin top surface 71, and has another end in the z direction that is connected to the resin sixth region 743. The resin fourth region 741 is inclined with respect to the resin top surface 71 and the y-z plane. The resin fifth region 742 has one end in the z direction that is connected to the resin bottom surface 72, and has another end in the z direction that is connected to the resin sixth region 743. The resin fifth region 742 is inclined with respect to the resin bottom surface 72 and the y-z plane. The resin sixth region 743 has one end in the z direction that is connected to the resin fourth region 741, and has another end in the z direction that is connected to the resin fifth region 742. The resin sixth region 743 is along the y-z plane. As viewed in the z direction, the resin sixth region 743 is located outside the resin top surface 71 and the resin bottom surface 72. A portion of each of the second terminals 52 is exposed from the resin sixth region 743.

As shown in FIG. 4, the resin side surface 75 includes a resin seventh region 751, a resin eighth region 752, and a resin ninth region 753. The resin seventh region 751 has one end in the z direction that is connected to the resin top surface 71, and has another end in the z direction that is connected to the resin ninth region 753. The resin seventh region 751 is inclined with respect to the resin top surface 71 and the x-z plane. The resin eighth region 752 has one end in the z direction that is connected to the resin bottom surface 72, and has another end in the z direction that is connected to the resin ninth region 753. The resin eighth region 752 is inclined with respect to the resin bottom surface 72 and the x-z plane. The resin ninth region 753 has one end in the z direction that is connected to the resin seventh region 751, and has another end in the z direction that is connected to the resin eighth region 752. The resin ninth region 753 is along the x-z plane. As viewed in the z direction, the resin ninth region 753 is located outside the resin top surface 71 and the resin bottom surface 72.

As shown in FIGS. 3 and 4, the resin side surface 76 includes a resin tenth region 761, a resin eleventh region 762, and a resin twelfth region 763. The resin tenth region 761 has one end in the z direction that is connected to the resin top surface 71, and has another end in the z direction that is connected to the resin twelfth region 763. The resin tenth region 761 is inclined with respect to the resin top surface 71 and the x-z plane. The resin eleventh region 762 has one end in the z direction that is connected to the resin bottom surface 72, and has another end in the z direction that is connected to the resin twelfth region 763. The resin eleventh region 762 is inclined with respect to the resin bottom surface 72 and the x-z plane. The resin twelfth region 763 has one end in the z direction that is connected to the resin tenth region 761, and has another end in the z direction that is connected to the resin eleventh region 762. The resin twelfth region 763 is along the x-z plane. As viewed in the z direction, the resin twelfth region 763 is located outside the resin top surface 71 and the resin bottom surface 72.

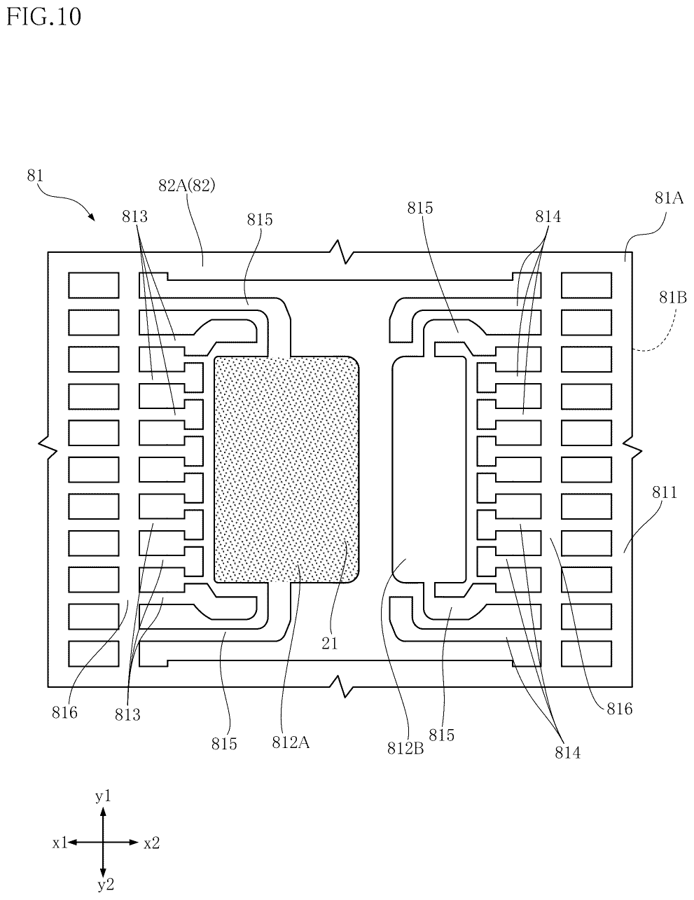

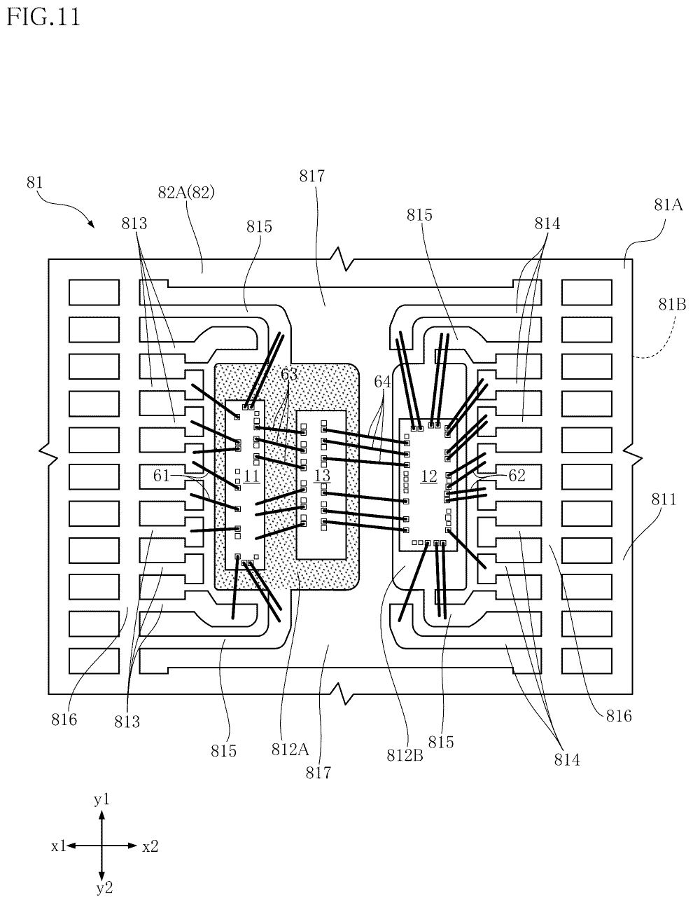

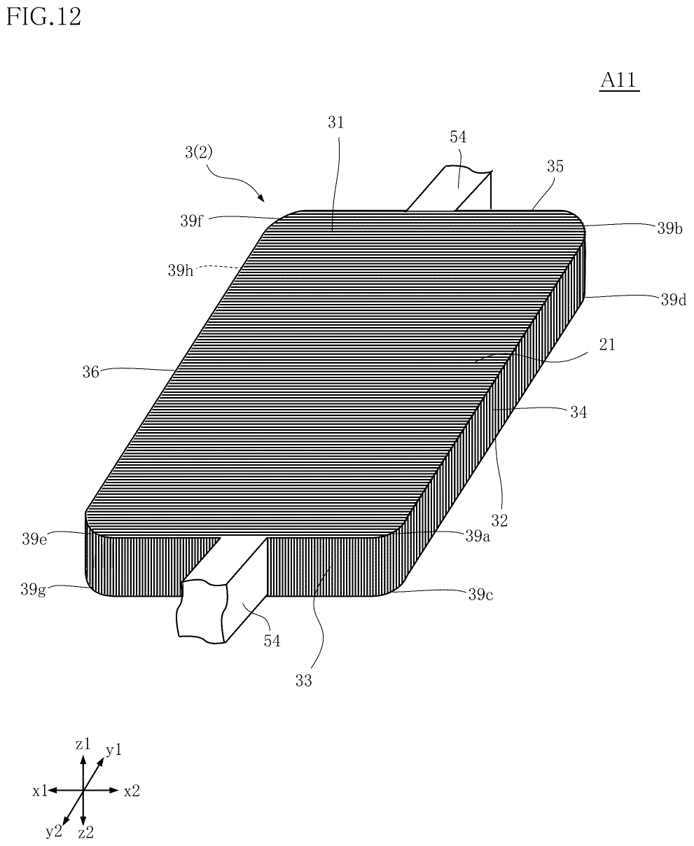

Next, an example of a manufacturing method of the semiconductor device A10 is described below with reference to FIGS. 10 to 11. FIGS. 10 to 11 are plane views of steps related to a manufacturing method of the semiconductor device A10.

First, as shown in FIG. 10, a lead frame 81 is prepared. The lead frame 81 is a plate-shaped material. In the present embodiment, a base material of the lead frame 81 is made of Cu. The lead frame 81 may be formed by subjecting a metal plate to an etching process or the like, or may be formed by subjecting a metal plate to a punching process. In the present embodiment, the lead frame 81 is subjected to an etching process. The lead frame 81 has an obverse surface 81A and a reverse surface 81B that are spaced apart in the z direction. Further, the lead frame 81 includes an outer frame 811, a first die pad 812A, a second die pad 812B, first leads 813, second leads 814, connection parts 815, and a dam bar 816. Of these, the outer frame 811 and the dam bar 816 do not constitute the semiconductor device A10. The first die pad 812A is a portion that will later become the first die pad 3. The second die pad 812B is a portion that will later become the second die pad 4. The first leads 813 are portions that will later become the first terminals 51 and the pad parts 53. The second leads 814 are portions that will later become the second terminals 52 and the pad parts 55. The third leads 815 are portions that will later become the pair of connection parts 54 and the pair of connection parts 56.

Next, as shown in FIG. 10, an uneven part 21 is formed on a predetermined portion of the lead frame 81. In the present embodiment, the uneven part 21 is formed on the entire first die pad 812A. That is, the uneven part 21 is formed on each of the first die pad 812A portion (the stippled portion in FIG. 10) of the obverse surface 81A, the first die pad 812A portion of the reverse surface 81B, and the side surface (the surface connected to the obverse surface 81A and the reverse surface 81B) of the first die pad 812A. In the step of forming the uneven part 21, at first, the portion of the lead frame 81 where the uneven part 21 is not formed is masked. Then, the lead frame 81 with the mask is immersed in an etching solution. Thereby, the lead frame 81 without the mask is eroded by the etching solution, so that the uneven part 21 is formed with the fine irregular concavity/convexity. The uneven part 21 may be formed by a dry etching.

Next, as shown in FIG. 11, the first semiconductor element 11 and the insulating element 13 are bonded to the first die pad 812A by a die bonding, and the second semiconductor element 12 is bonded to the second die pad 812B by a die bonding. Then, each of the pluralities of wires 61 to 64 is formed by a wire bonding.

Next, the sealing resin 7 is formed. the sealing resin 7 is formed by means of transfer molding. In the current step, the lead frame 81 is accommodated in a mold with cavities. In this case, the portion of the lead frame 81 that will become the conductive member 2 covered by the sealing resin 7 in the semiconductor device A10 will be accommodated in one of the cavities. Then, fluidized resin is poured from the pot into each of the cavities via runners. After the sealing resin 7 that has fluidized in the cavities is solidified, resin burrs located outside of each cavity are removed with high-pressure water or the like. This completes the formation of the sealing resin 7.

Thereafter, by dicing into individual pieces, the first leads 813 and the second leads 814, which were connected to each other by the outer frame 811 and the dam bar 816, are spaced apart as appropriate. By the process shown above, the semiconductor device A10 is manufactured.

Next, effects and advantages of the semiconductor device A10 are described.

In the present embodiment, the uneven part 21 is provided on the first die pad 3. The uneven part 21 is formed with a plurality of fine recesses and is covered by the sealing resin 7. The sealing resin 7 enters the fine recesses to be solidified, hence having improved adhesion to the first die pad 3 due to the anchor effect. Therefore, the detachment of the sealing resin 7 from the first die pad 3 is prevented. This allows the semiconductor device A10 to suppress dielectric breakdown caused by the detachment of the sealing resin 7.

Further, in the present embodiment, the uneven part 21 is disposed over the entire surface of the obverse surface 31 of the first die pad 3. The obverse surface 31 is more likely to be affected heat stress than the other surfaces and to occur the detachment because the first semiconductor element 11 is mounted on it. The uneven part 21 is disposed on the obverse surface 31, which suppress the detachment of the sealing resin 7 at the obverse surface 31. Further, even when the detachment of the sealing resin 7 occurs from the first die pad 3, it is possible to suppress the detachment from extending to the insulating element 13. In the present embodiment, the uneven part 21 is disposed over the entire surface of each of the side surfaces 33 to 36 that is connected to the obverse surface 31. Therefore, it is possible to suppress the sealing resin 7 from the detachment at the boundary between the obverse surface 31 and each of the side surfaces 33 to 36, which is likely to be a starting point of the detachment. Further, in the present embodiment, the uneven part 21 is also provided on the corner parts 39a to 39h. Therefore, it is possible to suppress the sealing resin 7 from the detachment at the corner parts 39a to 39h, which is likely to be a starting point of the detachment.

Further, in the present embodiment, the uneven part 21 is formed by an etching. This is advantageous in forming the uneven part 21 on a broad area. Further, the uneven part 21 may be formed with the fine irregular concavity/convexity.

FIGS. 12 to 15 show a variation of the semiconductor device A10 according to the first embodiment. In these figures, the elements that are identical or similar to those of the above-described embodiment are denoted by the same reference signs, and the descriptions thereof are omitted.

### First Variation

FIG. 12 is an illustration for describing a semiconductor device A11 according to a first variation of the first embodiment. FIG. 12 is a perspective view of a first die pad 3 of the semiconductor device A11, corresponding to FIG. 9. Fine recesses are formed to be regularly aligned in the uneven part 21 according to the first variation. In the present variation, the uneven part 21 is formed by a laser process. In the present variation, at the obverse surface 31 and the reverse surface 32, the uneven part 21 is formed with recesses that extends in the x direction and is regularly aligned in the y direction. This is formed by irradiating a laser beam and scanning it in the x direction, and by repeating the scanning in the x direction while moving the laser irradiation position in the y direction. Further, at the side surfaces 33 to 36, the uneven part 21 is formed with recesses that extends in the z direction and is regularly aligned in the x direction or the y direction. This is formed by irradiating a laser beam and scanning it in the z direction, and by repeating the scanning in the z direction while moving the laser irradiation position in the x direction or the y direction. The laser scanning direction at each surface is not limited. Further, at each surface, the uneven part 21 may be formed with overlapping recesses extending in multiple directions. For example, at the obverse surface 31, the uneven part 21 may be formed in a manner that recesses extending in the x direction and aligned in the y direction overlaps with recesses extending in the y direction and aligned in the x direction. Forming method of the uneven part 21 is not limited, including a stamping process. For example, the uneven part 21 may be formed by forming the lead frame 81 by punching a metal plate, and in a subsequent process, performing a crushing process using a die with an uneven inner surface. As understood from the first variation, forming method of the uneven part 21 is not specifically defined.

### Second Variation

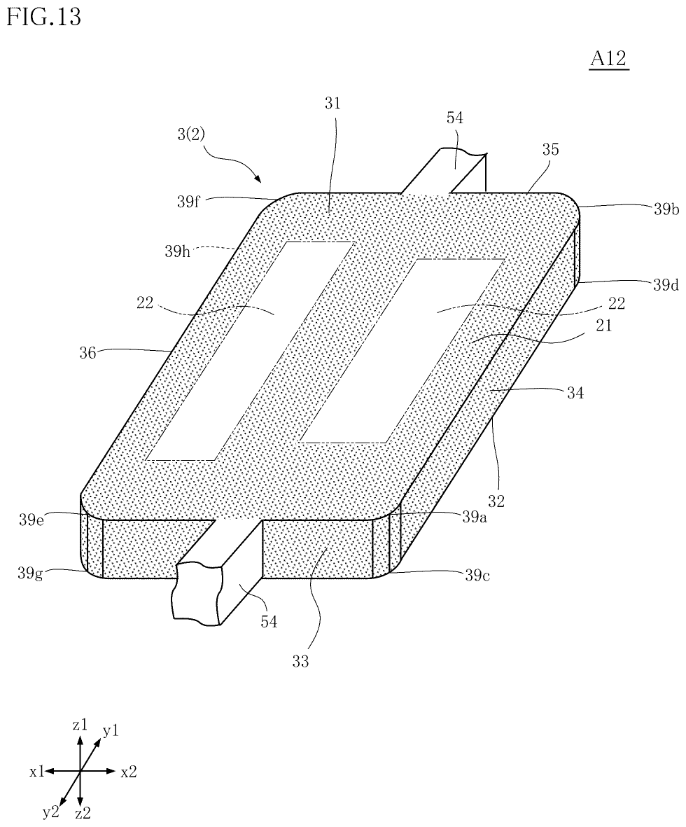

FIG. 13 is an illustration for describing a semiconductor device A12 according to a second variation of the first embodiment. FIG. 13 is a perspective view of a first die pad 3 of the semiconductor device A12, corresponding to FIG. 9. At the obverse surface 31, the first die pad 3 according to the second variation includes a region 22 where the uneven part 21 is not provided. In other words, the uneven part 21 is not provided on the entire surface but only on a portion of the obverse surface 31. In FIG. 13, the regions 22 of the obverse surface 31 are shown as imaginary lines (a two-dot chain lines). The regions 22 are the areas where the first semiconductor element 11 and the insulating element 13 are mounted. The regions 22 does not need to be formed with the uneven part 21, because it is not in contact with the sealing resin 7 when the first semiconductor element 11 and the insulating element 13 are mounted. In the case where the uneven part 21 is formed by a laser or the like, the area to form the uneven part 21 can be reduced, so that the time to form the uneven part 21 can be shortened. As understood from the second variation, the uneven part 21 does not need to be formed on the entire surface but only on a portion of each surface.

### Third Variation

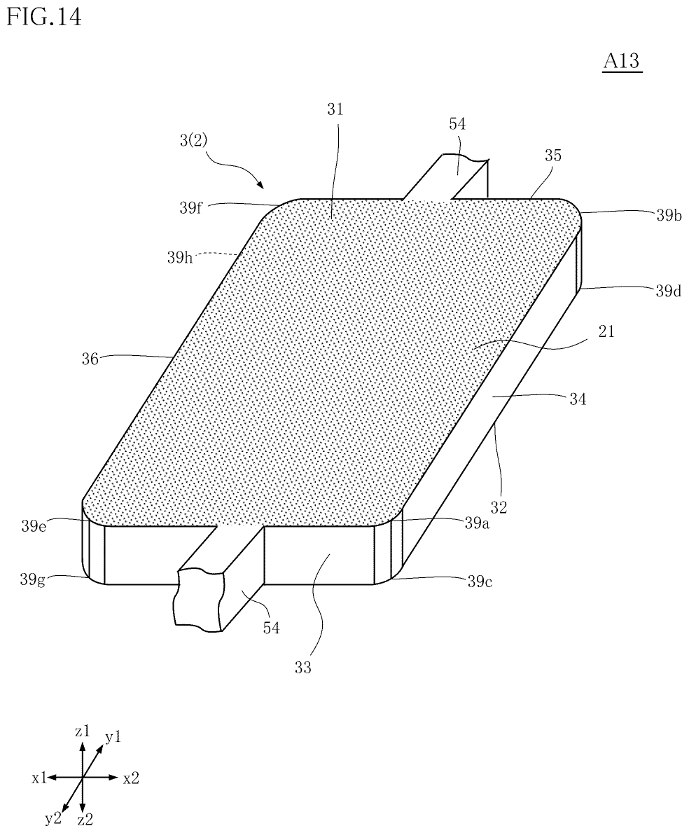

FIG. 14 is an illustration for describing a semiconductor device A13 according to a third variation of the first embodiment. FIG. 14 is a perspective view of a first die pad 3 of the semiconductor device A13, corresponding to FIG. 9. The first die pad 3 according to the third variation includes the uneven part 21 only on the obverse surface 31. In other words, the uneven part 21 is not provided on the reverse surface 32 and the side surfaces 33 to 36. Since the uneven part 21 is provided on the obverse surface 31 of the first die pad 3, the present variation can suppress the detachment of the sealing resin 7 at the obverse surface 31. Further, even when the detachment occurs, it is possible to suppress the detachment from extending to the insulating element 13.

### Fourth Variation

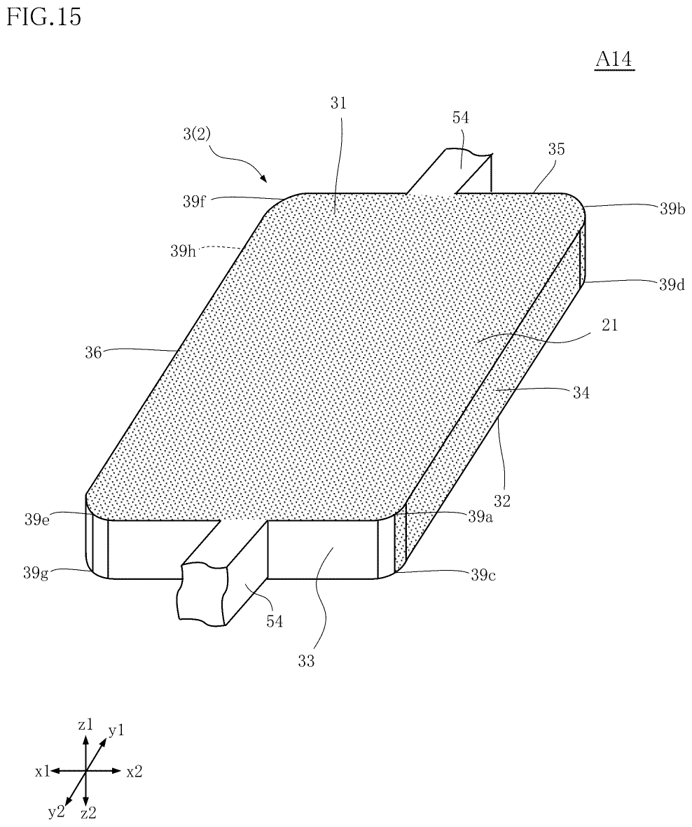

FIG. 15 is an illustration for describing a semiconductor device A14 according to a fourth variation of the first embodiment. FIG. 15 is a perspective view of a first die pad 3 of the semiconductor device A14, corresponding to FIG. 9. The first die pad 3 according to the fourth variation includes the uneven part 21 only on the obverse surface 31 and the side surface 34. In other words, the uneven part 21 is not provided on the reverse surface 32 and the side surfaces 33, 35, 36. The present variation also can suppress the sealing resin 7 from the detachment at the boundary between the obverse surface 31 and the side surface 34. Since the relevant boundary is closer to the insulating element 13 compared to other boundaries, suppressing the detachment can effectively suppress the extension of the detachment to the insulating element 13. Further, since the relevant boundary is closer to the second die pad 4 than other boundaries, it is possible to effectively suppress the occurrence of dielectric breakdown due to a crack that occurs when the detachment extends to the second die pad 4.

As understood from the third variation and the fourth variation, the uneven part 21 does not need to be provided on all the obverse surface 31, the reverse surface 32, and the side surfaces 33 to 36, but may be provided only on a part of the surfaces. The surface where the uneven part 21 is provided is not limited. Note that it is preferable to form the uneven part 21 at least on the obverse surface 31.

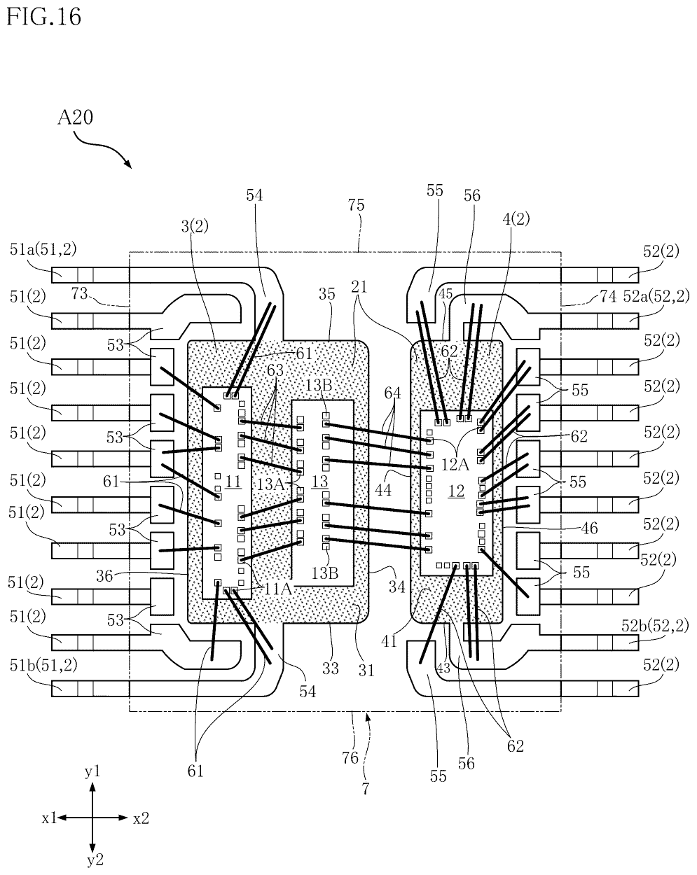

FIGS. 16 to 22 show other embodiments of the present disclosure. In these figures, the elements that are identical or similar to those of the above-described embodiment are denoted by the same reference signs.

### Second Embodiment

FIG. 16 is an illustration for describing a semiconductor device A20 according to a second embodiment of the present disclosure. FIG. 16 is a plan view showing the semiconductor device A20, corresponding to FIG. 2. In FIG. 16, for the sake of convenience of understanding, the sealing resin 7 is transparent and an outer shape of the sealing resin 7 is indicated by an imaginary line (a two-dot chain line). The semiconductor device A20 of the present embodiment differs from the first embodiment in that the uneven part 21 is additionally formed on the second die pad 4. The configuration and operation of other portions of the present embodiment are the same as those of the first embodiment. In addition, various parts of the above-described first embodiment and each of the variations may be combined arbitrarily.

In the present embodiment, the uneven part 21 is additionally provided on the entire surface of each of the obverse surface 41, the reverse surface 42, and the side surfaces 43 to 46 of the second die pad 4. The uneven part 21 does not need to be provided on the entire surface (may be provided only on a part) of each surface of the second die pad 4, and does not need to be provided on all the obverse surface 41, the reverse surface 42, and the side surfaces 43 to 46 (may be provided only on a part of the surfaces). The uneven part 21 applied for the second die pad 4 includes the same variations of the first die pad 3 shown in each variation of the first embodiment may be applied.

In the present embodiment, since the uneven part 21 is provided on the first die pad 3, improved adhesion of the sealing resin 7 to the first die pad 3 can suppress the detachment of the sealing resin 7. This allows the semiconductor device A20 to suppress dielectric breakdown caused by the detachment of the sealing resin 7. In addition, the semiconductor device A20 provides same advantages as the semiconductor device A10 due to common configurations with the semiconductor device A10. Further, in the present embodiment, the uneven part 21 is additionally provided on the second die pad 4, the detachment of the sealing resin 7 on the second die pad 4 may also be suppressed. This may suppress the occurrence of dielectric breakdown by a crack that occurs when the detachment extends to the first die pad 3.

The uneven part 21 may be formed not only on the first die pad 3 and the second die pad 4, but also on the entire conductive member 2. In this case, when the uneven part 21 is formed by an etching or the like, the lead frame 81 does not need to be masked, hence simplifying the manufacturing steps.

### Third Embodiment

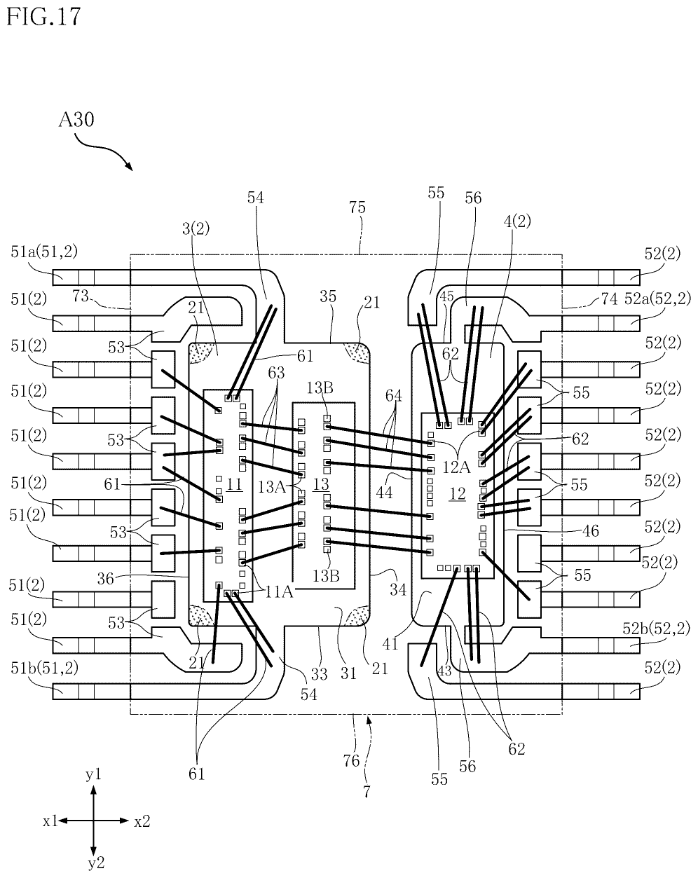

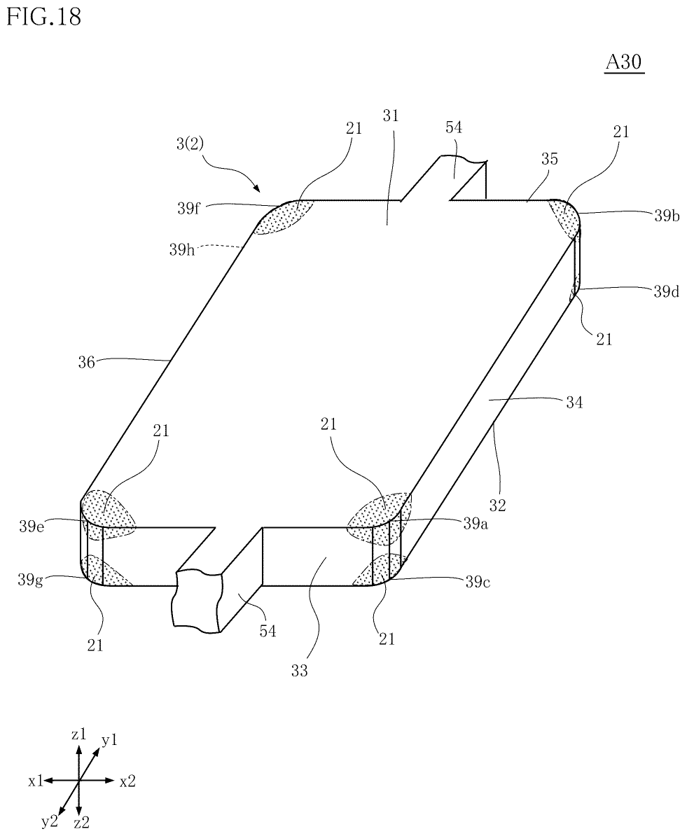

FIGS. 17 to 18 are illustrations for describing a semiconductor device A30 according to a third embodiment of the present disclosure. FIG. 17 is a plan view showing the semiconductor device A30, corresponding to FIG. 2. In FIG. 17, for the sake of convenience of understanding, the sealing resin 7 is transparent and an outer shape of the sealing resin 7 is indicated by an imaginary line (a two-dot chain line). FIG. 18 is a perspective view of a first die pad 3 of the semiconductor device A30, corresponding to FIG. 9. The semiconductor device A30 of the present embodiment differs from the first embodiment in that the uneven part 21 is provided only on each corner part of the first die pad 3. The configuration and operation of other portions of the present embodiment are the same as those of the first embodiment. In addition, various parts of the above-described first to second embodiments and each of the variations may be combined arbitrarily.

In the present embodiment, the uneven part 21 is provided only on each of the corner parts 39a to 39h of the first die pad 3. In FIGS. 17 and 18, each uneven part 21 is surrounded by an imaginary line (a double-dashed line) and is stippled. As shown in FIG. 18, the uneven parts 21 are provided on the four corners of each of the obverse surface 31, the reverse surface 32, and the side surfaces 33 to 36 to be spaced apart from each other. The uneven part 21 provided on each of the corner parts 39a to 39h is spaced apart from each other.

In the present embodiment, since the uneven part 21 is provided on the first die pad 3, improved adhesion of the sealing resin 7 to the first die pad 3 can suppress the detachment of the sealing resin 7. This allows the semiconductor device A30 to suppress dielectric breakdown caused by the detachment of the sealing resin 7. In addition, the semiconductor device A30 provides the same advantages as the semiconductor device A10 due to common configurations with the semiconductor device A10. Further, the present embodiment may suppress the sealing resin 7 from the detachment at the corner parts 39a to 39h, which is likely to be a starting point of the detachment, and may reduce the area where the uneven part 21 is provided as much as possible.

The present embodiment has been described as the case where the uneven parts 21 are provided on all the corner parts 39a to 39h, but not limited to this. The uneven part 21 may only be provided on one of the corner parts 39a to 39h. For example, the uneven parts 21 may be provided only on the corner parts 39a, 39b, 39e, 39f at the side of the obverse surface 31, or may be provided only on the corner parts 39a, 39b, 39c, 39d at the side of the side surface 34. In these cases, the area where the uneven part 21 is provided may be further reduced while suppressing the detachment of the portion where the detachment is likely to occur or where the occurrence of the detachment leads more problems.

### First Variation

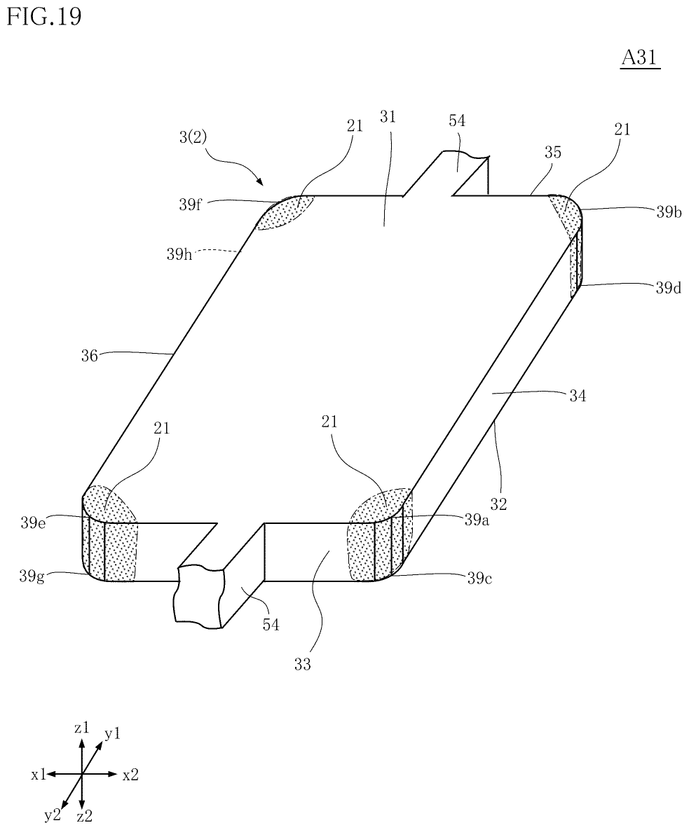

FIG. 19 is an illustration for describing a semiconductor device A31 according to a first variation of the third embodiment. FIG. 19 is a perspective view of a first die pad 3 of the semiconductor device A31, corresponding to FIG. 9. In the semiconductor device A31, the uneven part 21 provided on the corner part 39a and the uneven part 21 provided on the corner part 39c are connected to each other. Further, the uneven part 21 provided on the corner part 39b and the uneven part 21 provided on the corner part 39d are connected to each other. Further, the uneven part 21 provided on the corner part 39e and the uneven part 21 provided on the corner part 39g are connected to each other. Further, the uneven part 21 provided on the corner part 39f and the uneven part 21 provided on the corner part 39h are connected to each other. As understood from the first variation, the uneven parts 21 provided on the corner parts 39a to 39h need not all be spaced apart from each other.

### Fourth Embodiment

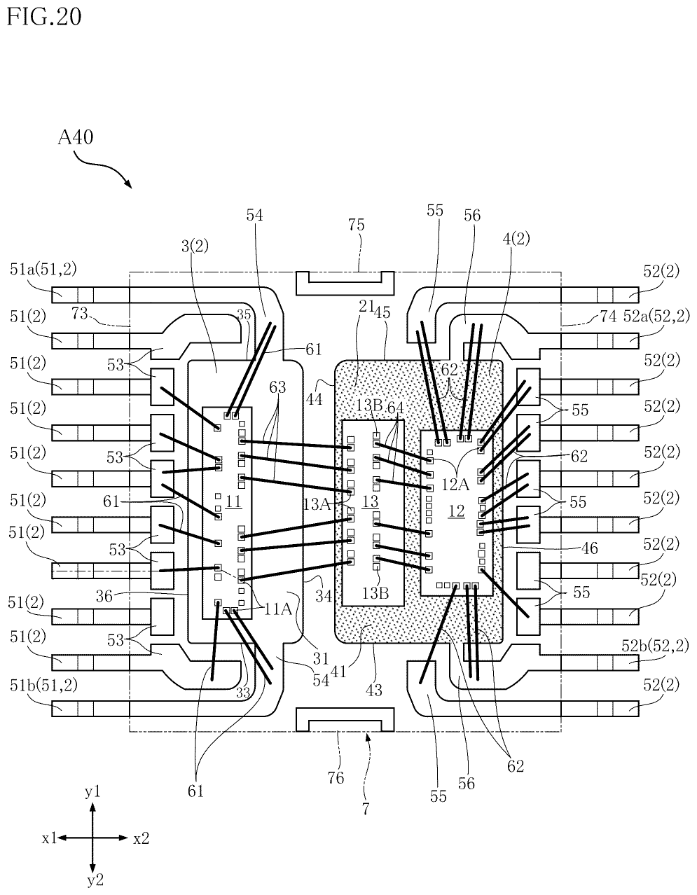

FIG. 20 is an illustration for describing a semiconductor device A40 according to a fourth embodiment of the present disclosure. FIG. 20 is a plan view showing the semiconductor device A40, corresponding to FIG. 2. In FIG. 20, for the sake of convenience of understanding, the sealing resin 7 is transparent and an outer shape of the sealing resin 7 is indicated by an imaginary line (a two-dot chain line). The semiconductor device A40 of the present embodiment differs from the first embodiment in that the insulating element 13 is mounted on the second die pad 4. The configuration and operation of other portions of the present embodiment are the same as those of the first embodiment. In addition, various parts of the above-described first to third embodiments and each of the variations may be combined arbitrarily.

In the present embodiment, the second die pad 4 has a larger dimension in the x direction compared to the first embodiment. On the other hand, the first die pad 3 has a smaller dimension in the x direction compared to the first embodiment. In the present embodiment, the insulating element 13 is mounted on the second die pad 4. Further, in the present embodiment, the uneven part 21 is not provided on the first die pad 3, while the uneven part 21 is provided on the second die pad 4 on which the insulating element 13 is mounted.

According to the present embodiment, since the semiconductor device A40 includes the uneven part 21 provided on the second die pad 4, improved adhesion of the sealing resin 7 to the second die pad 4 can suppress the detachment of the sealing resin 7. This allows the semiconductor device A40 to suppress dielectric breakdown caused by the detachment of the sealing resin 7. In addition, the semiconductor device A40 provides the same advantages as the semiconductor device A10 due to common configurations with the semiconductor device A10.

### Fifth Embodiment

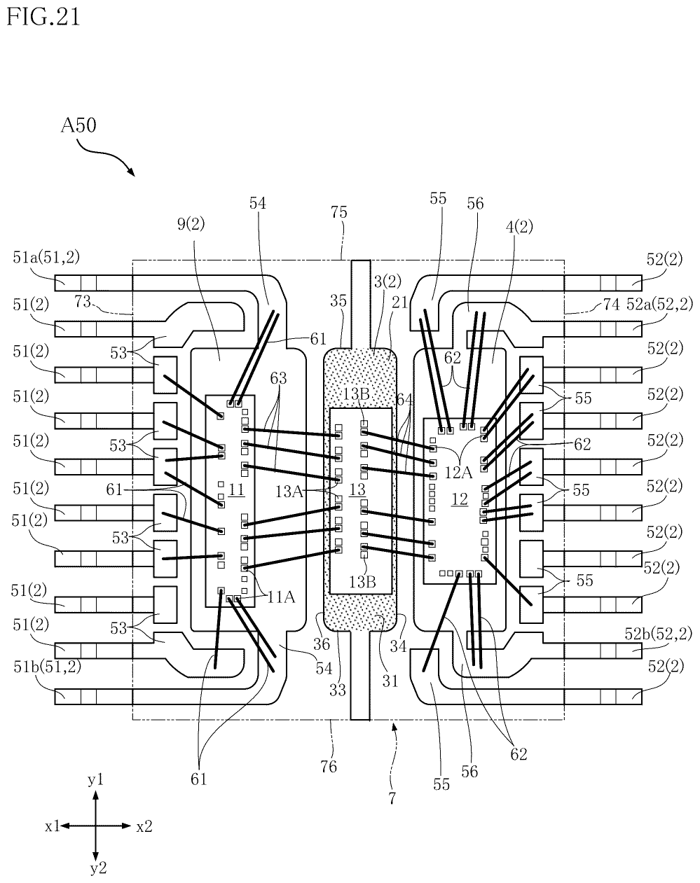

FIG. 21 is an illustration for describing a semiconductor device A50 according to a fifth embodiment of the present disclosure. FIG. 21 is a plan view showing the semiconductor device A50, corresponding to FIG. 2. In FIG. 21, for the sake of convenience of understanding, the sealing resin 7 is transparent and an outer shape of the sealing resin 7 is indicated by an imaginary line (a two-dot chain line). The semiconductor device A50 of the present embodiment differs from the first embodiment in that it further includes a third die pad 9 and the first semiconductor element 11 is mounted on the third die pad 9. The configuration and operation of other portions of the present embodiment are the same as those of the first embodiment. In addition, various parts of the above-described first to fourth embodiments and each of the variations may be combined arbitrarily.

In the present embodiment, the first die pad 3 is disposed at the center of the semiconductor device A50 in the x direction. The first die pad 3 extends to both ends of the sealing resin 7 in the y direction, has an end at the y1 side in the y direction that is exposed from the resin side surface 75, and has an end at the y2 side in the y direction is exposed from the resin side surface 76. Further, the conductive member 2 includes the third die pad 9. The third die pad 9 is disposed at the x1 side in the x direction with respect to the first die pad 3, and is spaced apart from the first die pad 3. In the present embodiment, the first semiconductor element 11 is mounted on the third die pad 9.

In the present embodiment, since the uneven part 21 is provided on the first die pad 3, improved adhesion of the sealing resin 7 to the first die pad 3 can suppress the detachment of the sealing resin 7. This allows the semiconductor device A50 to suppress dielectric breakdown caused by the detachment of the sealing resin 7. In addition, the semiconductor device A50 provides the same advantages as the semiconductor device A10 due to common configurations with the semiconductor device A10.

### Sixth Embodiment

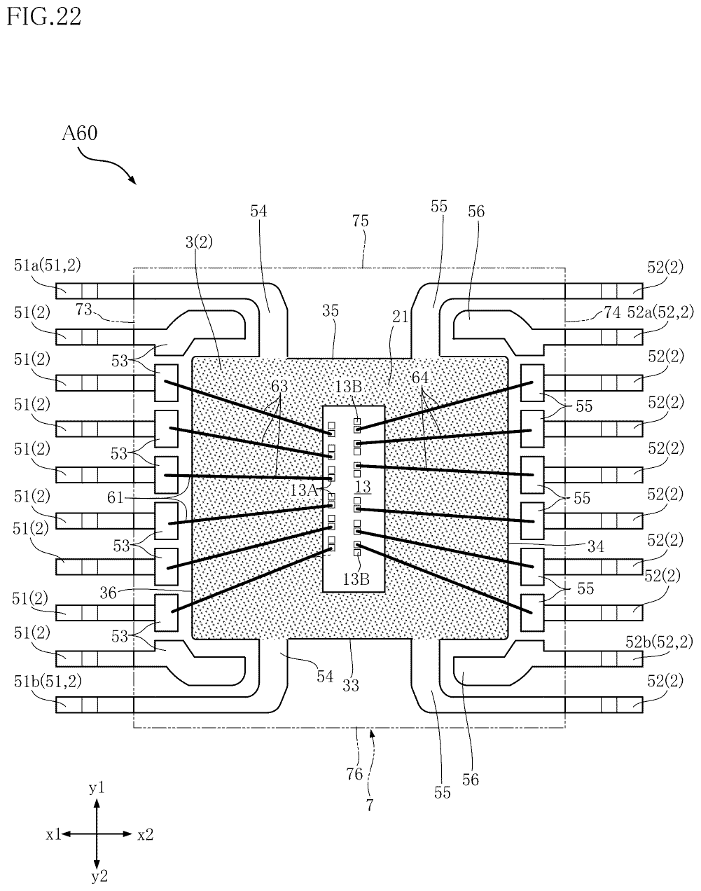

FIG. 22 is an illustration for describing a semiconductor device A60 according to a sixth embodiment of the present disclosure. FIG. 22 is a plan view showing the semiconductor device A60, corresponding to FIG. 2. In FIG. 22, for the sake of convenience of understanding, the sealing resin 7 is transparent and an outer shape of the sealing resin 7 is indicated by an imaginary line (a two-dot chain line). The semiconductor device A60 of the present embodiment differs from the first embodiment in that it does not include the first semiconductor element 11 and the second semiconductor element 12. The configuration and operation of other portions of the present embodiment are the same as those of the first embodiment. In addition, various parts of the above-described first to fifth embodiments and each of the variations may be combined arbitrarily.

In the present embodiment, the semiconductor device A60 does not include the first semiconductor element 11 and the second semiconductor element 12. Also, the semiconductor device A60 does not include the second die pad 4 and the wires 61, 62. Only the insulating element 13 is mounted on the first die pad 3, each wire 63 is electrically bonded to the pad part 53, and each wire 64 is electrically bonded to the pad part 55.

In the present embodiment, since the uneven part 21 is provided on the first die pad 3, improved adhesion of the sealing resin 7 to the first die pad 3 can suppress the detachment of the sealing resin 7. This allows the semiconductor device A60 to suppress dielectric breakdown caused by the detachment of the sealing resin 7. In addition, the semiconductor device A60 provides the same advantages as the semiconductor device A10 due to common configurations with the semiconductor device A10. Note that the semiconductor device A60 may further include the first semiconductor element 11 (a controlling element), the second semiconductor element 12 (a driving element), and other elements. The insulating element 13 may incorporate circuits that function as element, controlling or may incorporate circuits that function as a driving element. As understood from the present embodiment, elements to be mounted are not limited except for the insulating element.

The present disclosure is not limited to the foregoing embodiments. The specific configuration of each part of the semiconductor device according to the present disclosure can be varied in design in many ways. The present disclosure includes the embodiments described in the following clauses.

### Clause 1.

A semiconductor device comprising:
an insulating element (13);
a conductive member (2) on which the insulating element is mounted; and
a sealing resin (7) covering the insulating element,
wherein the conductive member includes an uneven part (21) covered by the sealing resin.

### Clause 2.

The semiconductor device according to clause 1, wherein the conductive member includes a first die pad (3) on which the insulating element is mounted, and
the uneven part includes a first region that is provided on the first die pad.

### Clause 3.

The semiconductor device according to clause 2, wherein the first die pad includes an obverse surface (31) on which the insulating element is mounted, and
the first region is provided on the obverse surface.

### Clause 4.

The semiconductor device according to clause 3, wherein the first region is provided only on a part of the obverse surface.

### Clause 5.

The semiconductor device according to clause 3 or 4, wherein the first die pad includes a first side surface (33) connected to the obverse surface, and
the uneven part includes a second region provided on the first side surface.

### Clause 6.

The semiconductor device according to clause 5, wherein the second region is provided only on a part of the first side surface.

### Clause 7.

The semiconductor device according to clause 5 or 6, wherein the first die pad includes a second side surface (34) connected to the obverse surface and the first side surface, and
the uneven part includes a third region provided on the second side surface.

### Clause 8.

The semiconductor device according to clause 7, wherein the third region is provided only on a part of the second side surface.

### Clause 9.

The semiconductor device according to clause 7 or 8, wherein at a first corner part (39a) where the obverse surface, the first side surface, and the second side surface are connected to each other, the first region is provided on the obverse surface, the second region is provided on the first side surface, and the third region is provided on the second side surface.

### Clause 10.

The semiconductor device according to any one of clauses 7 to 9, wherein the first die pad includes a third side surface (35) connected to the obverse surface and the second side surface,
the uneven part includes:
   a fourth region provided on the obverse surface to be spaced apart from the first region;
   a fifth region provided on the second side surface to be spaced apart from the third region; and
   a sixth region provided on the third side surface, and
at a second corner part (39b9 where the obverse surface, the second side surface, and the third side surface are connected to each other, the fourth region is provided on the obverse surface, the fifth region is provided on the second side surface, and the sixth region is provided on the third side surface.

### Clause 11.

The semiconductor device according to any one of clauses 7 to 10, wherein the first die pad includes a reverse surface (32) facing opposite to the obverse surface in a thickness direction,
the uneven part includes:
   a seventh region provided on the first side surface to be spaced apart from the second region;
   an eighth region provided on the second side surface to be spaced apart from the third region; and
   a ninth region provided on the reverse surface, and
at a third corner part (39c) where the first side surface, the second side surface, and the reverse surface are connected to each other, the seventh region is provided on the first side surface, the eighth region is provided on the second side surface, and the ninth region is provided on the reverse surface.

### Clause 12.

The semiconductor device according to any one of clauses 2 to 11, wherein the conductive member includes a second die pad (4) that is spaced apart from the first die pad, and
the uneven part includes a tenth region that is provided on the second die pad.

### Clause 13.

The semiconductor device according to clause 12, further comprising:
a controlling element (11) electrically connected to the insulating element; and
a driving element (12) electrically connected to the insulating element,
wherein the controlling element is mounted on the first die pad, and
the driving element is mounted on the second die pad.

### Clause 14.

The semiconductor device according to any one of clauses 1 to 13, wherein fine recesses are irregularly aligned in the uneven part.

### Clause 15.

The semiconductor device any one of clauses 1 to 13, wherein fine recesses are regularly aligned in the uneven part.

REFERENCE NUMERALS

| | |
|---|---|
| A10-A14, A20, A30, A31: Semiconductor | |
| device | |
| A40, A50, A60: Semiconductor device | |
| 11: First semiconductor element | 11A: Electrode |
| 12: Second semiconductor element | 12A: Electrode |
| 13: Insulating element | 13A: Fist electrode |
| 13B: Second electrode | 131: First relay electrode |
| 132: Second relay electrode | 19: Conductive bonding |
| | material |
| 2: Conductive member | 21: Uneven part |
| 22: Region | 3: First die pad |
| 31: Obverse surface | 32: Reverse surface |
| 33-36: Side surface | 39a-39h: Corner part |
| 4: Second die pad | 41: Obverse surface |
| 42: Reverse surface | 43-46: Side surface |
| 9: Third die pad | 51, 51a, 51b: First |
| | terminal |
| 53: Pad part | 54: Connection part |
| 52, 52a, 52b: Second terminal | 555: Pad part |
| 56: Connection part | 61, 62, 63, 64: Wire |
| 7: Sealing resin | 71: Resin top surface |
| 72: Resin bottom surface | 73-76: Resin side surface |
| 731: Resin first region | 732: Resin second region |
| 733: Resin third region | 741: Resin fourth region |
| 742: Resin fifth region | 743: Resin sixth region |
| 751: Resin seventh region | 752: Resin eighth region |
| 753: Resin ninth region | 761: Resin tenth region |
| 762: Resin eleventh region | 763: Resin twelfth region |
| 81: Lead frame | 81A: Obverse surface |
| 812A: First die pad | 812B: Second die pad |
| 813: First lead | 814: Second lead |
| 815: Connection part | 816: Dam bar |

1. A semiconductor device comprising:
an insulating element;
a conductive member on which the insulating element is mounted; and
a sealing resin covering the insulating element,
wherein the conductive member includes an uneven part covered by the sealing resin.

2. The semiconductor device according to claim 1, wherein the conductive member includes a first die pad on which the insulating element is mounted, and
the uneven part includes a first region that is provided on the first die pad.

3. The semiconductor device according to claim 2, wherein the first die pad includes an obverse surface on which the insulating element is mounted, and
the first region is provided on the obverse surface.

4. The semiconductor device according to claim 3, wherein the first region is provided only on a part of the obverse surface.

5. The semiconductor device according to claim 3, wherein the first die pad includes a first side surface connected to the obverse surface, and
the uneven part includes a second region provided on the first side surface.

6. The semiconductor device according to claim 5, wherein the second region is provided only on a part of the first side surface.

7. The semiconductor device according to claim 5, wherein the first die pad includes a second side surface connected to the obverse surface and the first side surface, and
the uneven part includes a third region provided on the second side surface.

8. The semiconductor device according to claim 7, wherein the third region is provided only on a part of the second side surface.

9. The semiconductor device according to claim 7, wherein at a first corner part where the obverse surface, the first side surface, and the second side surface are connected to each other, the first region is provided on the obverse surface, the second region is provided on the first side surface, and the third region is provided on the second side surface.

10. The semiconductor device according to claim 7, wherein the first die pad includes a third side surface connected to the obverse surface and the second side surface,
the uneven part includes:
a fourth region provided on the obverse surface to be spaced apart from the first region;
a fifth region provided on the second side surface to be spaced apart from the third region; and
a sixth region provided on the third side surface, and
at a second corner part where the obverse surface, the second side surface, and the third side surface are connected to each other, the fourth region is provided on the obverse surface, the fifth region is provided on the second side surface, and the sixth region is provided on the third side surface.

11. The semiconductor device according to claim 7, wherein the first die pad includes a reverse surface facing opposite to the obverse surface in a thickness direction,
the uneven part includes:
a seventh region provided on the first side surface to be spaced apart from the second region;
an eighth region provided on the second side surface to be spaced apart from the third region; and
a ninth region provided on the reverse surface, and
at a third corner part where the first side surface, the second side surface, and the reverse surface are connected to each other, the seventh region is provided on the first side surface, the eighth region is provided on the second side surface, and the ninth region is provided on the reverse surface.

12. The semiconductor device according to claim 2, wherein the conductive member includes a second die pad that is spaced apart from the first die pad, and
the uneven part includes a tenth region that is provided on the second die pad.

13. The semiconductor device according to claim 12, further comprising:
a controlling element electrically connected to the insulating element; and
a driving element electrically connected to the insulating element,
wherein the controlling element is mounted on the first die pad, and
the driving element is mounted on the second die pad.

14. The semiconductor device according to claim 1, wherein fine recesses are irregularly aligned in the uneven part.

15. The semiconductor device claim 1, wherein fine recesses are regularly aligned in the uneven part.
